(19) United States
(12) Patent Application Publication
(10) Pub. No.: US 2010/0043876 A1
(43) Pub. Date: Feb. 25, 2010

(54) SOLVENT SYSTEM

(75) Inventors: Richard Tuttle, Pittsburgh, PA (US); Matthew Ladd Reitz, Allison Park, PA (US); Brian E. Woodworth, Pittsburgh, PA (US)

Correspondence Address: FOLEY AND LARDNER LLP;SUITE 500, 3000 K STREET NW, WASHINGTON, DC, 20007, US

(73) Assignee: Plextronics, Inc.

(21) Appl. No.: 12/541,500

(22) Filed: Aug. 14, 2009

Related U.S. Application Data
(60) Provisional application No. 61/090,464, filed on Aug. 20, 2008.

(51) Int. Cl. H01L 31/00; H01B 1/12; H01L 31/0236; H01L 31/18

(52) U.S. Cl. 136/256; 252/500; 136/263; 438/71; 257/E31.13

(57) ABSTRACT

Improved organic photovoltaic cells including a composition useful for forming an active layer which comprises (a) at least one p-type material, (b) at least one n-type material, (c) at least one first solvent and (d) at least one second solvent, wherein the first solvent is different from the second solvent, and the first solvent comprises at least one alkylbenzene or benzocyclohexane, and the second solvent comprises at least one carbocyclic compound. The second solvent can be used in lesser amounts but can improve efficiency in cells.

### RELATED APPLICATIONS

This application claims priority to U.S. provisional application Ser. No. 61/090,464 filed on Aug. 20, 2008, which is incorporated by reference in its entirety.

### BACKGROUND

Organic Photovoltaics (OPVs) represent an important technology area, offering an environmentally friendly source of power. However, there is still an ongoing need for developing improved ink compositions that are used to form the OPV device active layer. Particularly, there is interest in ink compositions that are industrially acceptable and commercially friendly, such as compositions with non-halogenated solvents. There is also a continuing need for improving the efficiency of OPVs. One method of improving device efficiency can involve improving performance of the active layer in an OPV device.

### SUMMARY

Provided herein are, among other things, compositions, devices, methods of making and methods of using such compositions and devices. For example, described herein are solvent systems which can be used to form ink compositions that help fulfill the industrial and commercial needs as well as ink compositions that can be used to form, for example, OPV devices with improved efficiency.

In one embodiment, a composition is provided that comprises (a) at least one p-type material, (b) at least one n-type material, (c) at least one first solvent and (d) at least one second solvent, wherein the first solvent is different from the second solvent, and the first solvent comprises at least one alkylbenzene or benzocyclohexane, and the second solvent comprises at least one carbocyclic compound.

In another embodiment, a composition is provided that comprises (a) at least one p-type material comprising a conjugated polymer, (b) at least one n-type material comprising a fullerene derivative, (c) at least one first solvent and (d) at least one second solvent, wherein the first solvent is different from the second solvent, and the first solvent comprises at least one alkylbenzene or benzocyclohexane, and the second solvent comprises at least one carbocyclic compound, and wherein the composition is substantially free of halogenated compounds.

In a further embodiment, a photovoltaic device is provided comprising an anode electrode, a cathode electrode, and active layer located between the anode electrode and the cathode electrode; wherein the active layer is formed using a composition as provided.

In another embodiment, a method is provided comprising the steps of (a) combining at least one p-type material, at least one n-type material, at least one first solvent and at least one second solvent, to form a composition, wherein the first solvent is different from the second solvent, and the first solvent comprises at least one alkylbenzene compound, and the second solvent comprises at least one carbocyclic compound and (b) applying the composition to a surface.

In yet another embodiment, a method of improving the efficiency of a photovoltaic device is provided, the method comprising adding to an active layer ink composition, an amount of at least one second solvent sufficient to increase the average surface roughness of the active layer formed from the active layer ink composition, wherein the active layer ink composition comprises at least one n-type material, at least one p-type material and at least one first solvent comprising at least one alkylbenzene or benzocyclohexane, and the at least one second solvent comprises at least one carbocyclic compound.

In another further embodiment, a photovoltaic device is provided comprising an anode electrode, a cathode electrode, and active layer located between the anode electrode and the cathode electrode; wherein the active layer is formed according to the methods provided.

One advantage of some embodiments is the ability to improve efficiency of photovoltaic devices.

Another advantage some embodiments is in providing a less hazardous active layer ink composition.

Another advantage of some embodiments is in providing a less hazardous method of forming a photovoltaic device active layer.

Yet another advantage of some embodiments is in providing an industrially friendly method of preparing active layer ink compositions.

Still, another advantage of some embodiments is in providing an industrially friendly method of making a photovoltaic device.

### BRIEF DESCRIPTION OF FIGURES

FIG. 1 is an AFM 3-dimensional surface image of a typical active layer formed with only toluene as the solvent.

FIG. 2 is another AFM 3-dimensional surface image of a typical active layer formed with 94% toluene and 6% salicylaldehyde as the co-solvents.

FIG. 3 is another AFM 3-dimensional surface image of a typical active layer formed with 98% toluene and 2% anisole as the co-solvents.

FIG. 4 is another AFM 3-dimensional surface image of a typical active layer formed with 98% toluene and 2% methyl salicylate as the co-solvents.

### DETAILED DESCRIPTION

The solvent systems described herein may be used to form OPV active layers without the use of halogenated solvents, which can be hazardous and/or undesirable for industrial processes. Further, the solvent systems may be used in the active layer ink compositions to obtain better performing active layers. These solvent systems can comprise two or more solvents and can be combined with active layer components, such as, for example, poly-3-hexylthiophene (P3HT) and fullerene derivatives, to form an active layer ink composition. The solvent systems can comprise a first solvent and a second solvent, both of which are further described below. Although, the second solvent(s) typically constitutes a small percentage of the ink composition, it can dramatically increase the efficiency of the active layer.

Organic photovoltaic devices (OPVs)

Solar cells are described in, for example, Hoppe and Sariciftci, J. Mater. Res., Vol. 19, No. 7, July 2004, 1924-1945, which is hereby incorporated by reference, including the figures. See also, for example, Sun, Saricifcti (Eds.), Organic Photovoltaics, Mechanisms, Materials, Devices including descriptions and chapters on device efficiency, power conversion efficiency (PCE), and testing methods.

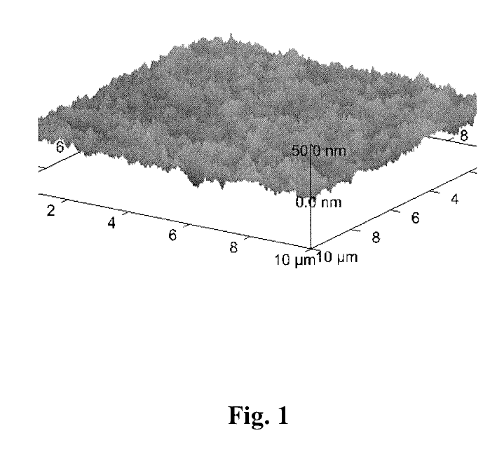

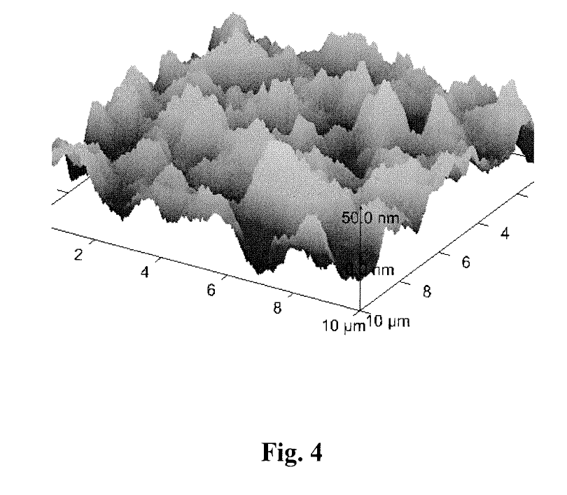

FIG. 1 of Hoppe et al., illustrates some components of a conventional solar cell. See also, for example, Dennler et al., “Flexible Conjugated Polymer-Based Plastic Solar Cells: From Basics to Applications,” Proceedings of the IEEE, vol. 93, no. 8, August 2005, 1429-1439, including FIGS. 4 and 5. Various architectures for the solar cell can be used, including inverted solar cells. Important elements include the active layer, an anode, a cathode, and a substrate to support the larger structure. In addition, a hole transport layer can be used, and one or more conditioning layers can be used. The active layer can comprise a P/N composite, including a P/N bulk heterojunction.

The following references describe photovoltaic materials and devices:

US Patent Publication 2006/0076050 to Williams et al., “Heteroatomic Regioregular Poly(3-Substitutedthiophenes) for Photovoltaic Cells,” (Plextronics) which is hereby incorporated by reference, including working examples and drawings.

US Patent Publication 2006/0237695 (Plextronics), “Copolymers of Soluble Poly(thiophenes) with Improved Electronic Performance,” which is hereby incorporated by reference including working examples and drawings.

U.S. Pat. No. 7,147,936 to Louwet et al.

In addition, US Patent Publication 2006/0175582 “Hole Injection/Transport Layer Compositions and Devices” describes hole injection layer technology, (Plextronics) which is hereby incorporated by reference including working examples and drawings.

Although compositions described herein are described in the context of OPVs, these compositions may be equally applicable to other devices employing organic photoactive layers. See, for instance, U.S. provisional application Ser. No. 61/043,654 filed on Apr. 9, 2008, hereby incorporated by reference in its entirety. Such devices may have hole collection layers, hole injection layers, or hole transport layers in which the compositions and methods of the present application may be applicable.

### OPV Electrodes, Hole Injection and Hole Transport Layers

Electrodes, including anodes and cathodes, are known in the art for photovoltaic devices. See, for example, Hoppe et al. article cited above. Known electrode materials can be used. Transparent conductive oxides can be used. Transparency can be adapted for a particular application. For example, the anode can be indium tin oxide (ITO), including ITO supported on a substrate. Substrates can be rigid or flexible.

If desired, hole injection and hole transport layers can be used. A hole transport layer (HTL) can be, for example, PEDOT:PSS as known in the art. See, for example, Hoppe et al. article cited above.

### OPV Active Layer

The active layer of an OPV can comprise semiconducting materials such as n-type and p-type materials. In the present embodiments, the active layer comprises both p-type and n-type materials. In some cases, the active layer may further comprise trace amounts of solvents.

One advantage of the present embodiments is that the n-type and the p-type materials may be chosen to maximize the difference between the LUMO level of the n-type with the HOMO level of the p-type, while still maintaining photo carrier generation within the active layer.

### Active Layer P-Type Material

The p-type material can comprise an organic material such as an organic polymeric material. For example, the p-type material can comprise a conjugated polymer or a conducting polymer, comprising a polymer backbone having a series of conjugated double bonds. It can comprise a homopolymer or a copolymer including a block copolymer or a random copolymer, or a terpolymer. Examples include polythiophene, polypyrrole, polyaniline, polyfluorene, polyphenylene, polyphenylene vinylene, and derivatives, copolymers, and mixtures thereof.

In one embodiment, the p-type material comprises a conjugated polymer comprising at least some conjugated unsaturation in the backbone. The p-type material can comprise a conjugated polymer soluble or dispersible in organic solvent or water. Conjugated polymers are described in for example T. A. Skotheim, Handbook of Conducting Polymers, 3^{rd} Ed. (two vol), 2007; Meijer et al., Materials Science and Engineering, 32 (2001), 1-40; and Kim, Pure Appl. Chem., 74, 11, 2031-2044, 2002. The p-type active material can comprise a member of a family of similar polymers which have a common polymer backbone but are different in the derivatized side groups to tailor the properties of the polymer. For example, a polythiophene can be derivatized with alkyl side groups including methyl, ethyl, hexyl, dodecyl, and the like.

In another embodiment the p-type material comprises copolymers and block copolymers which comprise, for example, a combination of conjugated and non-conjugated polymer segments, or a combination of a first type of conjugated segment and a second type of conjugated segment. For example, these can be represented by AB or ABA or BAB systems wherein, for example, one block such as A is a conjugated block and another block such as B is an non-conjugated block or an insulating block. Or alternately, each block A and B can be conjugated. The non-conjugated or insulating block can be for example an organic polymer block, an inorganic polymer block, or a hybrid organic-inorganic polymer block including for example addition polymer block or condensation polymer block including for example thermoplastic types of polymers, polyolefins, polysilanes, polyesters, PET, and the like. Block copolymers are described in, for example, U.S. Pat. No. 6,602,974 to McCullough et al., and US Patent Publication No. 2006/0278867 to McCullough et al. published Dec. 14, 2006, each incorporated herein by reference in its entirety.

In a particular embodiment, the p-type material comprises a polythiophene. Polythiophenes and derivatives thereof are known in the art. They can be a polymer comprising a thiophene in the backbone. They can be homopolymers or copolymers, including block copolymers. They can be soluble or dispersible. They can be regioregular. For example, they can have at least 80%, or at least 90%, or at least 95%, or at least 98%, or at least 99% regioregularity. In particular, optionally substituted-alkoxy- and optionally substituted alkyl-substituted polythiophenes can be used. In particular, regioregular polythiophenes can be used as described in, for example, U.S. Pat. Nos. 6,602,974 and 6,166,172 to McCullough et al., as well as McCullough et al., J. Am. Chem. Soc. 115:4910 (1993), including homopolymers and block copolymers. See also Plextronics (Pittsburgh, Pa.) commercial products. Soluble alkyl- and alkoxy-substituted polymers and copolymers can be used including poly(3-hexylthiophene). Other examples can be found in U.S. Pat. Nos. 5,294,372 and 5,401,537 to Kochem et al. U.S. Pat. Nos. 6,454,880 and 5,331,183 further describe active layers.

Soluble materials or well dispersed materials can be used in the stack to facilitate processing.

Additional examples of p-type materials and polythiophenes can be found in WO 2007/011739 (Gaudiana et al.) which describes polymers having monomers which are, for example, substituted cyclopentadithiophene moieties, and which is hereby incorporated by reference in its entirety including formulas.

### Active Layer N-Type Material

The active layer can comprise an n-type material comprising at least one fullerene structure. Fullerenes are known in the art. Fullerenes can be described as spheroidal carbon compounds. For example, the fullerene surface can present [6,6] bonding and [6,5] bonding as known in the art. The fullerene can have a surface comprising six-membered and five-membered rings. Fullerenes can be for example C60, C70, or C84, and additional carbon atoms can be added via derivative groups. See for example Hirsch, A.; Brettreich, M., Fullerenes: Chemistry and Reactions, Wiley-VCH Verlag, Weinheim, 2005, which is hereby incorporated by reference including teachings for fullerene nomenclature and synthesis, derivatization, reduction reactions (Chapter 2), nucleophilic additions (Chapter 3), cycloadditions (Chapter 4), hydrogenation (Chapter 5), radical additions (Chapter 6), transition metal complex formation (Chapter 7), oxidation and reactions with electrophiles (Chapter 8), halogenation (Chapter 9), regiochemistry (Chapter 10), cluster modification (Chapter 11), heterofullerenes (Chapter 12), and higher fullerenes (Chapter 13). Methods described herein can be used to synthesize fullerene derivatives and adducts.

The n-type material can comprise at least one fullerene derivative. The derivative compound can be for example an adduct. The fullerene derivative can be, for example, fullerenes comprising from 1 to 84, from 1 to 70, from 1 to 60, from 1 to 20, from 1 to 18, from 1 to 10, or from 1 to 6, from 1 to 5, or from 1 to 3 substituents, each covalently bonded to, for example, one or two carbons in the spheroidal carbon compounds. The fullerene derivative can comprise a fullerene covalently bonded by [4+2]cycloaddition to at least one derivative moiety, R.

Structures for the n-type material can be represented by:

F*-(R)n

and solvates, salts, and mixtures thereof,
wherein

n is at least one;

F is a spheroidal fullerene having a surface which comprises six-membered and five-membered rings; and

R comprises at least one optionally substituted, unsaturated or saturated, carbocyclic or heterocyclic first ring, wherein the first ring directly bonds to the fullerene.

Formula (I) represents an embodiment wherein C60 is bonded to n R groups, and the bonding is generically represented.

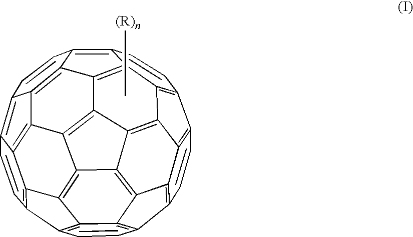

The first ring may or may not be substituted. The first ring can be a saturated ring or an unsaturated ring. The first ring can be a carbocyclic ring or a heterocyclic ring.

The first ring can be an optionally substituted four-membered, five-membered, or six-membered ring. It can in particular be an optionally substituted five-membered ring.

The R group can further comprise a second ring which is bonded to or fused with the first ring. The second ring can be optionally substituted. The second ring can be for example an aryl group which is fused to the first ring.

The first ring directly bonds to the fullerene. For example, the R group can covalently bond to the fullerene by a [4+2]cycloaddition. The R group can be covalently bonded to the fullerene by one or two covalent bonds, including two covalent bonds, including by two carbon-carbon bonds. The R group can be bonded to the fullerene surface by a covalent bond to one atom in the R group. Alternatively the R group can be bonded to the fullerene surface by covalent bonds to two atoms in the R group. The two atoms in the R group bonded to the fullerene can be adjacent to each other, or can be separated by from each other by 1 to 3 other atoms in the R group. The R group can be covalently bonded to the fullerene by two carbon-carbon bonds at a fullerene [6,6] position.

The fullerene can comprise only carbon. The fullerene can comprise at least one derivative group bonded to the fullerene besides R.

For example, fullerenes can be derivatized with electron withdrawing groups or electron releasing groups. Electron withdrawing groups and electron releasing groups are known in the art and can be found in Advanced Organic Chemistry, 5th Ed, by Smith, March, 2001.

The electron withdrawing group can be attached directly to the fullerene cage or via methano-bridges similar to the PCBM structure.

The electron donating group can be attached directly to the fullerene cage or via methano-bridges similar to the PCBM structure.

Fullerenes can be derivatized to improve their absorption in the visible range, relative to C60-PCBM. Improved absorption in the visible range may increase or improve the photocurrent of a photovoltaic device comprising the derivatized fullerene.

In one embodiment, F* is selected from C60, C70 and C84, and combinations thereof.

In one embodiment, R is selected from optionally substituted aryl and optionally substituted heteroaryl.

In one embodiment, R is selected from optionally substituted indene, optionally substituted naphthyl, optionally substituted phenyl, optionally substituted pyridinyl, optionally substituted quinolinyl, optionally substituted cyclohexyl, and optionally substituted cyclopentyl.

In one embodiment R is selected from indene, naphthyl, phenyl, pyridinyl, quinolinyl, cyclohexyl and cyclopentyl.

The value n can be an integer. In one embodiment, n can be from 1 to 84, or from 1 to 70, or from 1 to 60, or from 1 to 30, or from 1 to 10. In one embodiment n is from 1 to 6. In one embodiment n is from 1 to 3.

In one embodiment n is 1. In one embodiment n is 2. In one embodiment n is 3.

In one embodiment, the first ring is optionally substituted with at least one substituent selected from the group consisting of hydroxyl, acyl, acylamino, acyloxy, alkyl, substituted alkyl, alkoxy, substituted alkoxy, alkenyl, substituted alkenyl, alkynyl, substituted alkynyl, amino, substituted amino, aminoacyl, aryl, substituted aryl, aryloxy, substituted aryloxy, cycloalkoxy, substituted cycloalkoxy, carboxyl, carboxyl esters, cyano, thiol, thioalkyl, substituted thioalkyl, thioaryl, substituted thioaryl, thioheteroaryl, substituted thioheteroaryl, thiocycloalkyl, substituted thiocycloalkyl, thioheterocyclic, substituted thioheterocyclic, cycloalkyl, substituted cycloalkyl, halo, nitro, heteroaryl, substituted heteroaryl, heterocyclic, substituted heterocyclic, heteroaryloxy, substituted heteroaryloxy, heterocyclyloxy, or substituted heterocyclyloxy, or combination thereof.

In one embodiment n is 1 and R is indene. In one embodiment n is 2 and R is indene. In one embodiment n is 3 and R is indene. In one embodiment n is 4 and R is indene. In one embodiment n is 5 and R is indene. In one embodiment n is 6 and R is indene.

In one embodiment, R can be covalently bonded to the fullerene by [4+2]cycloaddition, alternatively called a [4+2]cycloadduct. Reactions including [4+2]cycloaddition reactions and Diels-Alder reactions are generally known in the art. A dienophile double bond can react with a diene to produce a six membered ring. See for example Advanced Organic Chemistry, Reactions, Mechanisms, and Structure, 2^{nd} Ed., J. March, 1977, including chapters on addition to carbon-carbon multiple bonds (e.g., Chapter 15). See also, Belik et al., Angew. Chem. Int. Ed. Engl. 1993, 32, 1, 78-80 (showing reaction of C60 with a C8 o-quinodimethane compound to form a C68 compound comprising the fullerene and the derivative moiety); and Puplovskis et al., Tetrahedron Letters, 38, 2, 285-288, 1997, 285-288 (showing reaction of C60 with C9 indene to form a C69 compound comprising the fullerene and the derivative moiety). The cycloaddition reaction can result in reaction at the [6,6] fullerene double bonds rather than [6,5] double bonds. Cycloaddition reactions are described in detail in Chapter 4, pages 101-183, of the Hirsch, Brettreich text, Fullerenes, Chemistry and Reactions, 2005.

One example of a fullerene derivative is an indene derivative. In addition, indene itself can be derivatized. Fullerene can be derivatized by methods described in for example Belik et al., Angew. Chem. Int. Ed. Engl., 1993, 32, No. 1, pages 78-80, which is hereby incorporated by reference. This paper describes addition to electron poor superalkene, C60, which can add radicals such as o-quinodimethane. It can be prepared in situ containing different functional groups and form very reactive dienes that can form [4+2] cycloadducts even with the least reactive dienophiles. This method provides good selectivity and stability.

The fullerene can comprise at least two derivative moieties, R, to form bis-adducts or at least three derivative moieties, R, to form tris-adducts. These substituents can be added to the fullerene by [4+2]cycloaddition. For example, Belik et al. show in Scheme 1, formula 3, a fullerene compound comprising two derivative moieties. In addition, two fullerenes can be covalently linked by one derivative moiety as shown in Scheme 2 of Belik et al.

While the various embodiments are not limited by theory, it is believed that the derivatization may disrupt the conjugation of the fullerene cage. Disrupting the conjugation effects the ionization potential and electron affinity of the derivatized fullerene.

In one embodiment, the active layer comprises at least one fullerene derivative comprising an electron withdrawing group.

Active layer n-type materials are also described in U.S. patent application Ser. No. 11/743,587, filed on May 2, 2007; and Ser. No. 61/016,420, filed on Dec. 21, 2007, both hereby incorporated by reference in their entirety.

### Active Layer Morphology

The active layer can be a p-n composite and, for example, can form a heterojunction including a bulk heterojunction. See, for example, the discussion of nanoscale phase separation in bulk heterojunctions in Dennler et al., “Flexible Conjugated Polymer-Based Plastic Solar Cells: From Basics to Applications,” Proceedings of the IEEE, vol. 93, no. 8, August 2005, 1429-1439.

The heterojunction layer can have phase separated domain on a scale of a about 5 to 50 nm as measured by Atomic Force Microscope (AFM). AFM analysis can be used to measure surface roughness and phase behavior.

The solvent systems described herein may allow formation of an active layer with large domain of the p- or n-type materials. Without wishing to be bound to any particular theory, it is believed that the active layer efficiency is better when large domains form.

As mentioned, the solvent system can comprise a first and a second solvent. The second solvent may contribute to surface roughness of the active layer. The influence of the second solvent on surface roughness can be seen in FIGS. 1-4, which are described in the working examples. Again, without wishing to be bound to any particular theory, it is believed that an increase in surface roughness may influence the active layer efficiency. Accordingly, in one embodiment, a method of improving the efficiency of a photovoltaic system comprises adding to an active layer ink composition, an amount of at least one second solvent, sufficient to increase the average surface roughness of the active layer formed from the ink composition. The increase in the average surface roughness is preferably at least about 1 nm. Preferably, the average surface roughness is increased to between about 5 nm and about 20 nm, or between about 6 nm and about 15 nm, or between about 8 nm and 10 nm.

### Active Layer Solvents

In the present embodiments, the composition used for forming an active layer can comprise at least one n-type material, at least one p-type material at least one first solvent and at least one second solvent. Alternatively, the composition may consist essentially of at least one n-type material, at least one p-type material at least one first solvent and at least one second solvent. The first solvent(s) and the second solvent(s), are selected from different groups of organic compounds. Although the groups may have some compounds in common, the first and second solvents are selected such that they are not structurally identical compounds.

### First Solvents

In some embodiments, the first solvent comprises at least one alkylbenzene. The alkylbenzene can have one or more alkyl substituents on the benzene ring. Preferably, the combined total number of carbon atoms in the substituent(s) is between 1 and 6. More preferably, the combined total number of carbon atoms in the substituent(s) is between 1 and 3.

Each substituent may have between 1 and 6 carbon atoms, preferably between 1 and 3 carbon atoms.

The substituents can be a linear, branched or cyclic.

The alkylbenzene can have between 1 and 6 alkyl substituents, preferably between 1 and 3 alkyl substituents. As a non-limiting example, the alkylbenzene can be a monoalkylbenzene, dialkylbenzene, trialkylbenzene or tetraalkylbenzene. As a further non-limiting example, the alkylbenzene can be toluene, o-xylene, m-xylene or p-xylene.

In some embodiments in which the first solvent is an alkylbenzene having two or more alkyl substituents, the two alkyl substituents, together with the carbon atoms of the benzene ring, can join together to form a 5 to 7-membered ring. For example, in a particular embodiment, the first solvent comprises benzocyclohexane (tetralin) or a derivative thereof.

In a particular embodiment, the first solvent consists essentially of benzocyclohexane (tetralin).

In one embodiment, the first solvent is a mixture of two or more different alkylbenzenes. That is, at least two alkylbenzenes in the mixture are not structurally identical. Each of the two or more different alkylbenzenes can have one or more alkyl substituents, where the total number of carbon atoms in the substituent(s) is between 1 and 6. In one example, the combined total number of carbon atoms in the substituent(s) is 3 or 4. In another example the combined total number of carbon atoms in the substituent(s) is 4 or 5. The substituents may be linear, branched or cyclic.

In one non-limiting example, the first solvent comprises a mixture of two or more alkylbenzenes selected from monoalkylbenzenes, dialkylbenzenes, trialkylbenzenes and tetraalkylbenzenes.

In another non-limiting example, the first solvent comprises a mixture of C₉₋₁₀ dialkyl and trialkylbenzenes.

In another non-limiting example, the first solvent comprises a mixture of two or more alkylbenzenes selected from propylbenzenes, butylbenzenes, ethylmethylbenzenes, 1,3,5-trimethylbenzenes and 1,2,4-trimethylbenzenes.

Mixtures of alkylbenzenes may be commercially obtained. For instance, Aromatic 100 and Aromatic 150 (also known under Solvesso 100 and Solvesso 150, respectively), available from ExxonMobil Corp. (Houston, Tex.), may be used as the first solvent. These commercial mixtures may contain trace amounts of naphthalene or alkylnapthalenes.

In a particular embodiment, the first solvent is a non-halogenated solvent. In a further embodiment, the first solvent does not contain a heteroatom.

In another embodiment, the first solvent consists essentially of at least one alkylbenzene.

In yet another embodiment, the first solvent comprises an alkylbenzene represented by

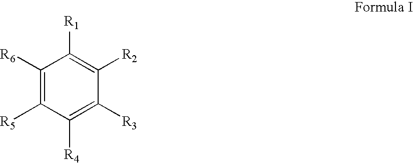

wherein R₁ is a C₁₋₃ alkyl and R₂, R₃, R₄, R₅ and R₆ are each independently hydrogen or a C₁₋₃ alkyl; provided that R₁, R₂, R₃, R₄, R₅ and R₆ combined have a total number of carbon atoms of between 1 and 6.

Preferably, in the above formula, substituents R₁, R₂, R₃, R₄, R₅ and R₆ combined have a total of 1, 2 or 3 carbon atoms. In a preferred embodiment, R₁ is methyl.

In one example, one of R₂, R₃, R₄, R₅ or R₆ is a C₁₋₃ alkyl.

In another example, two of R₂, R₃, R₄, R₅ or R₆ are independently a C₁₋₃ alkyl.

In another example, three of R₂, R₃, R₄, R₅ or R₆ are independently a C₁₋₃ alkyl.

In another example, four of R₂, R₃, R₄, R₅ or R₆ are independently a C₁₋₃ alkyl.

In another example, all of R₂, R₃, R₄, R₅ or R₆ are independently a C₁₋₃ alkyl.

In one example, all of R₂, R₃, R₄, R₅ or R₆ are hydrogen.

### Second Solvents

In the present embodiments, the second solvent can comprise at least one carbocyclic compound. Carbocyclic compounds comprise a cyclic arrangement of carbon atoms forming a ring. As a non-limiting example, a carbocyclic compound can comprise a benzene ring, a cyclohexane ring, or a cyclopentane ring, or can comprise a combination thereof.

The carbocyclic compound can further comprise a substituent comprising a heteroatom, an alkyl group, or both. In particular, the carbocyclic compound can contain a substituent selected from hydroxyl, acyl, acyloxy, carboxyl ester, alkyl, alkoxy, ketone or a combination thereof.

In some embodiments, the second solvent is a carbocyclic compound comprising a benzene ring having at least one substituent comprising a carbon atom (e.g., alkyl, alkenyl, etc.).

In another embodiments the second solvent is a carbocyclic compound comprising a benzene ring having at least one substituent comprising a heteroatom (e.g., amino, thiol, hydroxyl, etc.).

In another embodiment, the second solvent is a carbocyclic compound comprising a cyclohexane or a cyclopentane ring. In particular, the carbocyclic compound can be selected from cyclopentane, cyclohexane, cyclopentanone and cyclohexanone.

The carbocyclic compound can be a C₅₋₂₀, preferably a C₅₋₁₀ compound. That is, the compound, including its substituents, if any, contains a total of 5 to 15 carbon atoms or preferably 5 to 10 carbon atoms.

The second solvent may comprises a mixture of two or more different carbocyclic compounds selected from cyclopentane, cyclohexane and benzene.

In a non-limiting example, the second solvent comprises at least one carbocyclic compound selected from salicylaldehyde, methylsalicylate, anisol, tetralin, cyclopentane, cyclopentanone, cyclohexanone, methylbenzoate, anisaldehyde, mesitylene and 2-methoxybenzaldehyde.

In one embodiment, the second solvent consists essentially of a carbocyclic compound.

In another embodiment, the second solvent is non-halogenated.

In a particular embodiment, the second solvent comprises benzocyclohexane.

In a particular embodiment, the second solvent consists essentially of benzocyclohexane.

In another embodiment, the second solvent comprises a compound represented by

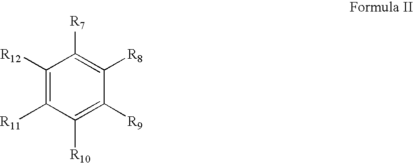

wherein R₇, R₈, R₉, R₁₀, R₁₁ and R₁₂ are each independently hydrogen, hydroxyl, acyl, acyloxy, carboxyl ester, C₁₋₅ alkyl or alkoxy. The total number of carbon atoms in the compound, including those in the substituents, if any, is less than 15, preferably less than 10.

The most preferred solvent system in the present embodiments is one in which the first solvent is toluene and the second solvent is salicyaldehyde.

### Solvent Properties

The first and second solvents play a significant role in forming an active layer (or bulk heterojunction layer) with improved performance. Certain physical properties of the first solvent, second solvent or the solvent system on the whole, factor into obtaining an optimum active layer morphology, which is further described below. For instance, the first or second solvents may selectively dissolve the n-type or p-type materials in the active layer.

Individual or relative boiling points of the first and second solvents can be important. For example, in one embodiment, the boiling point of the second solvent is higher than that of the first solvent. In another embodiment, the boiling point of the first solvent is greater than that of the second solvent.

In another embodiment, the boiling point of the first solvent is greater than 109° C. As a non-limiting example, the boiling point of the first solvent may be between about 109° C. and 210° C. including all individual values in the range.

In one embodiment, the boiling point of the second solvent is greater than about 49° C. As a non-limiting example, the boiling point of the second solvent may be between about 49° C. and 225° C., or between about 49° C. and about 250° C., including all individual values in these ranges.

Solubility parameters may also be used to select, for example, a suitable second solvent, first solvent or both. In particular, the Hansen Solubility Parameters may be used. The Hansen Solubility Parameters include dispersion, hydrogen and polarity parameters. The value for these parameters, for various compounds, can be found in Hansen, Charles M., Hansen Solubility Parameters; A User's Handbook, CRC Press, 2000, hereby incorporated by reference in its entirety.

Specifically, one approach for selecting the first or second solvents from a list of candidate compounds can involve selecting compounds with similar solubility, as predicted by the Hansen Solubility Parameters, as a solvent(s) already determined to be suitable for forming high performance active layers. Solvents with similar solubility may have similar values for all three Hansen Solubility Parameters. However, it may be possible that solvents with similar solubility may have similar values for less than all three of the parameters. In a non-limiting example, the first solvent is a compound with similar Hansen Solubility Parameters as o-dichlorobenzene, toluene or o-xylene. In another non-limiting example, the second solvent solubility parameters are similar to the solubility parameters of salicylaldehyde, methyl salicylate, anisaldehyde, or anisole. Solubility parameters of two solvents may be considered similar if they differ from each other by no more than about 5 MPa^{0.5}, no more than about 2 MPa^{0.5}, or no more than about 1 MPa^{0.5}.

Values for the dispersion, polarity and hydrogen bonding parameters can vary for the first and second solvents. As a non-limiting embodiment, the first solvent may have a dispersion parameter between about 17 MPa^{0.5} and about 20 MPa^{0.5}, a polarity parameter between about 0.5 MPa^{0.5} and 7.0 MPa^{0.5} and a hydrogen boding parameter between about 1.0 MPa^{0.5} and 7.0 MPa^{0.5}. As another non-limiting embodiment, the second solvent may have a dispersion parameter between about 15 MPa^{0.5} and about 20 MPa^{0.5}, a polarity parameter between about 0.5 MPa^{0.5} and about 15 MPa^{0.5}, such as between about 7 MPa^{0.5} and 11 MPa^{0.5}, and a hydrogen boding parameter between about 0.5 MPa^{0.5} and 18.0 MPa^{0.5}, such as between about 1.0 MPa^{0.5} and 7.0 MPa^{0.5}.

As discussed, the first and second solvents may be non-halogenated. In an alternative embodiment, the first and second solvents are substantially free of halogenated compounds. For example, the percentage by weight of halogenated compounds in the solvent system may be less than 10%, less than 5%, or less than 1% t.

### Solvent Amounts

In the solvent systems described herein, the first solvent amount can be greater than the second solvent amount. For example, the weight ratio of first solvent to second solvent may be between about 1000:1 and 2:1. More preferably, the mass ratio of first solvent to second solvent is between 100:1 and 10:1.

Typically, the first solvent in the solvent systems described herein is the majority component, on the basis of mass. For example, the percent by mass of first solvent in the composition(s) can be larger than 50%. In a non-limiting example, the percent mass of first solvent is between about 50% and 99%, including all values in the range. In another non-limiting example, the first solvent is present at between about 90% and 99% by mass, including all values in the range. As such, the percent mass of second solvent in the composition is typically less than 50% by mass. As a non-limiting example, the second solvent percent mass is between about 50% wt and 0.01%, more preferably between about 10% and 0.01%, including all individual values in the range.

In one embodiment, the solvent system comprises one first solvent and two or more different second solvents. Preferably, in such cases, the percent mass of the two or more second solvents, combined, is less than 50% of the solvent system. As a non-limiting example, a solvent system may comprise a first solvent, and two different second solvents. The mass percent of the first solvent can be, for example, about 50-98%, and each of the second solvents constitute 1-25% by mass of the solvent system.

### Active Layer Compositions

The compositions described herein may be used to form the active layer of a photovoltaic device. In particular, they may be commercially distributed as an “ink” for forming the active layer in OPVs. For example, the compositions can be applied to a surface of a material in an OPV and subsequently annealed to form the active layer. As such, the active layer will be substantially free of solvents. For example less than 2% or less than 1% of the solvents may remain in the active layer.

### Device Fabrication

Devices using the presently claimed inventions can be made according to known methods in the art. For example, the devices can be made using ITO as an anode material on a substrate. Other anode materials can include, for example, metals such as Au, carbon nanotubes (single or multiwalled), and other transparent conducting oxides. The resistivity of the anode can be maintained below, for example, 15 Ω/sq or less, 25 or less, 50 or less, or 100 or less, or 200 or less, or 250 or less. The substrate can be for example glass, plastics (PTFE, polysiloxanes, thermoplastics, PET, PEN and the like), metals (Al, Au, Ag), metal foils, metal oxides, (TiOx, ZnOx) and semiconductors, such as Si. The ITO on the substrate can be cleaned using techniques known in the art prior to device layer deposition. An optional hole transport layer (HTL) can be added using for example spin casting, ink jetting, doctor blading, spray casting, dip coating, vapor depositing, or any other known deposition method. The HTL can be for example PEDOT, PEDOT/PSS or TBD, or NPB, or Plexcore HTL (Plextronics, Pittsburgh, Pa.).

The thickness of the HTL layer can be, for example, from about 10 nm to about 300 nm thick, or from 30 nm to 60 nm, 60 nm to 100 nm, or 100 nm to 200 nm. The film then can be optionally dried/annealed at 110 to 200° C. for 1 min to an hour, optionally in an inert atmosphere. Methods for annealing are known in the art.

The active layer formulation can vary with respect to component amounts. The n- and p-type materials can be mixed in a ratio of for example from about 0.1 to 4.0 (p-type) to about 1 (n-type) based on a weight, or from about 1.1 to about 3.0 (p-type) to about 1 (n-type) or from about 1.1 to about 1.5 (p-type) to about 1 (n-type). The amount of each type of material or the ratio between the two types of components can be varied for the particular application.

In one embodiment, the n- and p-type materials combined constitute about 0.01% to about 0.1% by weight of the active layer ink composition. In other cases, the n- and p-type materials combined constitute about 0.8% to about 4% by weight of the active layer ink composition.

In one embodiment, the ink composition of the present embodiments is applied to at least one surface to form a film. Preferably the deposition surface(s) comprises a surface of a photovoltaic device element. Most preferably, the surface(s) comprises a surface of a hole transport layer, a surface of the anode, or a surface of a ink composition film. The ink composition may be deposited as multiple layers, for example as consecutive layers or with an intermediate layer(s) in between each deposited film.

The active layer can be formed by depositing the ink composition using a variety of known methods. For example, the ink composition can be deposited by spin casting, ink jetting, doctor blading, spray casting, dip coating, vapor depositing, or any other known deposition method, on top of the HTL film. The film is then annealed at about 40 to about 250° C., or from about 150 to 180° C., for about one minute to two hours, such as 10 min to an hour, in an inert atmosphere.

Next, a cathode layer can be added to the device, generally using for example thermal evaporation of one or more metals. For example, a 1 to 15 nm Ca layer is thermally evaporated onto the active layer through a shadow mask, followed by deposition of a 10 to 300 nm Al layer.

In some embodiments an optional interlayer may be included between the active layer and the cathode, and/or between the HTL and the active layer. This interlayer can be for example from 0.5 nm to about 100 nm, or from about 1 to 3 nm, thick. The interlayer can comprise an electron conditioning, a hole blocking, or an extraction material such as LiF, BCP, bathocuprine, fullerenes or fullerene derivatives, such as C60 and other fullerenes and fullerene derivatives discussed herein.

The devices can be then encapsulated using a glass cover slip sealed with a curable glue, or with other epoxy or plastic coatings. Cavity glass with a getter/desiccant may also be used.

In addition, the active layer can comprise additional ingredients including for example surfactants, dispersants, and oxygen and water scavengers.

The active layer can comprise multiple layers or be multi-layered.

The active layer composition can comprise a mixture in the form of a film.

The active layer may be formed on a flexible substrate.

Efficiency of the solar cell can be, for example, at least 3.75%, or at least 4%, or at least 4.5%, or at least 5%, or at least 6%. No particular upper limit for efficiency is present, but the range in efficiency can be, for example, 3.75% to 15%, or 3.75% to 10%. Methods known in the art can be used to measure efficiency.

The improvement in efficiency with the use of the second solvent can be, for example, at least 1%, or at least 10%, or at least 25%, or at least 50%.

### WORKING EXAMPLES

Various claimed embodiments are described further with use of non-limiting working examples. In the examples below, “C-60 indene” represents an indene di-substituted C₆₀ fullerene.

### Example 1

### Ink Composition 1—Toluene Only

An active layer ink composition was made, in an inert atmosphere, by dissolving 45.50 mg of P3HT and 45.50 mg of C-60 indene in 5.13 g of toluene. The active layer ink was placed on a shaker at 70° C. overnight, to allow the material to completely dissolve before the active layer deposition.

### Example 2

### Ink Composition 2—o-xylene (80%) and tetralin (20%)

An active layer ink composition was made, in an inert atmosphere, by dissolving 60.6 mg of P3HT and 60.6 mg of C-60 indene in a solvent system that includes 0.70 grams of tetralin and 2.80 grams of o-xylene. The active layer ink was placed on a shaker at 70° C. overnight, to allow the material to completely dissolve before the active layer deposition.

### Example 3

### Ink Composition 3—toluene (94%) and salicylaldehyde (6%)

An active layer ink composition was made, in an inert atmosphere, by dissolving 18.90 mg of P3HT and 18.90 mg of C-60 indene in a solvent system that includes 0.09 grams of salicylaldehyde and 2.07 grams of toluene. The active layer ink was placed on a shaker at 70° C. overnight, to allow the material to completely dissolve before the active layer deposition.

### Example 4

### Ink Composition 4—o-xylene (96%) and salicylaldehyde (4%)

An active layer ink composition was made, in an inert atmosphere, by dissolving 37.90 mg of P3HT and 37.90 mg of C-60 indene in a solvent system that includes 0.18 grams of salicylaldehyde and 4.20 grams of o-xylene. The active layer ink was placed on a shaker at 70° C. overnight, to allow the material to completely dissolve before the active layer deposition.

### Example 5

### Ink Composition 5—o-xylene (74%), tetralin (20%) and salicylaldehyde (6%)

An active layer ink composition was made, in an inert atmosphere, by dissolving 45.5 mg of P3HT and 45.5 mg of C-60 indene in a solvent system that includes 0.16 grams of salicylaldehyde, 0.53 grams of tetralin and 1.97 grams of o-xylene. The active layer ink was placed on a shaker at 70° C. overnight, to allow the material to completely dissolve before the active layer deposition.

### Example 6

### Ink Composition 6—toluene (94%) and methyl salicylate (6%)

An active layer ink composition was made, in an inert atmosphere, by dissolving 15.2 mg of P3HT and 15.2 mg of C-60 indene in a solvent system that includes 0.11 grams of methyl salicylate and 1.66 grams of toluene. The active layer ink was placed on a shaker at 70° C. overnight, to allow the material to completely dissolve before the active layer deposition.

### Example 7

### Ink Composition 7—toluene (98%) and anisole (2%)

An active layer ink composition was made, in an inert atmosphere, by dissolving 15.2 mg of P3HT and 15.2 mg of C-60 indene in a solvent system that includes 0.03 grams of anisole and 1.71 grams of toluene. The active layer ink was placed on a shaker at 70° C. overnight, to allow the material to completely dissolve before the active layer deposition.

### Example 8

### Ink Composition 8—tetralin (80%) toluene (15%) and salicylaldehyde (5%)

An active layer ink composition was made, in an inert atmosphere, by dissolving 60.6 mg of P3HT and 60.6 mg of C-60 indene in a solvent system that includes 0.38 grams of salicylaldehyde, 1.14 grams of toluene, and 6.07 grams of tetralin. The active layer ink was placed on a shaker at 70° C. overnight, to allow the material to completely dissolve before the active layer deposition.

### Example 9

### Ink Composition 8—tetralin (80%) toluene (15%) and anisaldehyde (5%)

An active layer ink composition was made, in an inert atmosphere, by dissolving 60.6 mg of P3HT and 60.6 mg of C-60 indene in a solvent system that includes 0.38 grams of anisaldehyde, 1.14 grams of toluene, and 6.06 grams of tetralin. The active layer ink was placed on a shaker at 70° C. overnight, to allow the material to completely dissolve before the active layer deposition.

### Examples 10-16

### Active Layer and Device Formation

The following procedure was used to form a device using each of compositions 1-9. Table 1 shows efficiency of the devices corresponding to each composition.

In order to make the devices, an ITO coated substrate was first treated under UV/ozone for 10 minutes. A Hole Transport Layer was deposited on the ITO coated substrate by spin casting. The HTL was either Plexcore OC HTL or poly(3,4-ethylenedioxythiophene)/poly(styrenesulfonate) (PEDOT/PSS) (both available from Sigma-Aldrich). Approximately 1 mL of the HTL was filtered as it was deposited on the substrate. The HTL material is then spun to achieve a 60 nm thick film. For example, in the case of PEDOT/PSS, the HTL material was spun in a two step process with 350 rpm for 5 seconds as the first step, then 6000 rpm for 1 minute as the second step. The HTL material was spun in a clean room environment but not in an inert atmosphere. The HTL/ITO coated substrate was then annealed at 175° C. for 30 minutes in an inert atmosphere.

The active layer formation, cathode formation, and glass encapsulation were all performed in an inert atmosphere. Approximately 1 mL of the active layer ink composition was filtered and deposited on the HTL coated substrate. The ink composition was then spun in a single step process at 600 rpm for 4 minutes. The substrate was then annealed for 30 minutes at 175° C. After annealing the device was placed in an MBraun MB200MOD (1800/750) vacuum chamber for cathode deposition. In this chamber, calcium and aluminum were vapor deposited at 10 nm and 200 nm respectively. The device was then coated with UV-cure glue, a small piece of glass was attached, and the glue was cured. The completed device was then tested.

FIGS. 1-4, are AFM images of a typical active layer formed from compositions 1, 3, 4, and 5, respectively. The device efficiencies obtained using compositions 1, 3, 4, and 5 for active layer formation are shown in Table 1. In this table, Jsc is the short circuit current density, Voc is the Voltage, the FF is the Fill Factor, and the E(%) is the efficiency percentage for the cell.

An AFM image of a typical active layer formed using composition 1, is shown in FIG. 1. The average surface roughness for this active layer was about 4 nm, as measured using the AFM imaging tools. The efficiency of a typical photovoltaic device having an active layer formed using composition 1, was 3.73%.

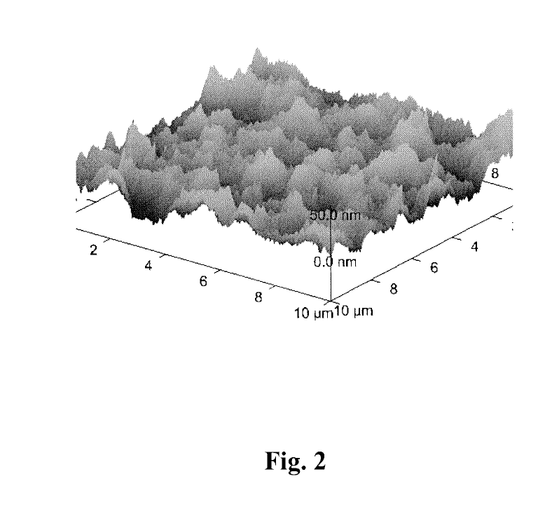

FIG. 2 shows a typical active layer formed using composition 3. As evident, the addition of 6% by weight of salicylaldehyde resulted in an increase in domain sizes and an increase in the average surface roughness to about 9 nm. The efficiency of a typical photovoltaic device having an active layer formed using composition 3, was about 5.12%.

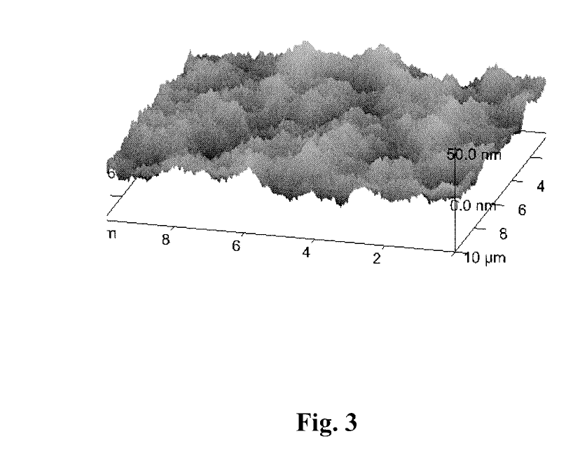

The active layer shown in FIG. 3, was formed using composition 5. In this case the addition of 2% by weight of anisole also resulted in an increase in domain size and surface roughness, which was about 6.6 nm. The efficiency of a typical photovoltaic device having an active layer formed using composition 5, was about 4.50%.

The active layer shown in FIG. 4, was formed using composition 4. Similar to salicylaldehyde and anisole, the addition of 6% by weight of methyl salicylate also resulted in an increase in domain size and surface roughness, which was about 15 nm. The efficiency of a typical photovoltaic device having an active layer formed using composition 4, was about 4.85%.

TABLE 1

| | P3HT | | | | | | | |
|---|---|---|---|---|---|---|---|---|
| | & c-60 | First | Second | Second | | | | |
| | Indene | Solvent | Solvent 1 | Solvent 2 | | | | |
| Composition | (% Vol) | (wt %) | (wt %) | (wt %) | Jsc | Voc (V) | FF | E (%) |
| 1 | 0.012 | Toluene | | | 7.3 | 0.85 | 0.59 | 3.73 |
| | | (100) | | | | | | |
| 2 | 0.024 | O- | Tetralin- | | 9.32 | 0.82 | 0.61 | 4.56 |
| | | xylene | 20 | | | | | |
| | | (80) | | | | | | |
| 3 | 0.012 | Toluene | Salicylaldehyde | | 9.82 | 0.82 | 0.65 | 5.12 |
| | | (94) | (6) | | | | | |
| 4 | 0.012 | O- | Salicylaldehyde | | 8.19 | 0.84 | 0.7 | 4.79 |
| | | xylene | (4) | | | | | |
| | | (96) | | | | | | |
| 5 | 0.024 | O- | Tetralin- | Salicylaldehyde | 9.74 | 0.83 | 0.62 | 4.97 |
| | | xylene | 20 | (6) | | | | |
| | | (74) | | | | | | |
| 6 | 0.012 | Toluene | Methyl | | 8.98 | 0.85 | 0.62 | 4.85 |
| | | (94) | Salicylate-6 | | | | | |
| 7 | 0.012 | Toluene | Anisole-2 | | 8.4 | 0.8 | 0.65 | 4.5 |
| | | (98) | | | | | | |
| 8 | 0.012 | Tetralin | Toluene (15) | Salicylaldehyde | 9.25 | 0.78 | 0.65 | 4.67 |
| | | (80) | | (5) | | | | |
| 9 | 0.012 | Tetralin | Toluene (15) | Anisaldehyde | 8.01 | 0.76 | 0.59 | 3.6 |
| | | (80) | | (5) | | | | |

### Additional Embodiments

The following additional embodiments were included in U.S. priority provisional application 61/090,0464:

### Embodiment 1

A composition comprising
at least one p-type material;
at least one n-type material;
at least one first solvent; and
at least one second solvent;
   wherein the first solvent is different from the second solvent, the first solvent comprises at least one alkylbenzene or benzocyclohexane, and
   the second solvent comprises at least one carbocyclic compound.

### Embodiment 2

The composition of embodiment 1, wherein the at least one p-type material comprises a conjugated polymer.

### Embodiment 3

The composition of embodiment 1, wherein the conjugated polymer comprises a regioregular polythiophene derivative.

### Embodiment 4

The composition of embodiment 1, wherein the n-type material comprises at least one fullerene derivative represented by:

F*-(R)n

and solvates, salts and mixtures thereof,

wherein n is at least one,
F* comprises a fullerene having a surface which comprises six-membered and five-membered rings; and
R comprises at least one optionally substituted, unsaturated or saturated, carbocyclic or heterocyclic first ring, wherein the first ring directly bonds to the fullerene.

### Embodiment 5

The composition of embodiment 4, wherein R is optionally substituted indene, optionally substituted naphthyl, optionally substituted phenyl, optionally substituted pyridinyl, optionally substituted quinolinyl, optionally substituted cyclohexyl, or optionally substituted cyclopentyl.

### Embodiment 6

The composition of embodiment 1, wherein the first solvent comprises at least one alkylbenzene having one or more alkyl substituents, wherein the total number of carbon atoms in the substituents combined is between 1 and 6.

### Embodiment 7

The composition of embodiment 1, wherein the first solvent comprises toluene, o-xylene, m-xylene, p-xylene, tetralin, or a combination thereof.

### Embodiment 8

The composition of embodiment 1, wherein the first solvent comprises a mixture of two or more different alkylbenzenes.

### Embodiment 9

The composition of embodiment 1, wherein the first solvent is a hydrocarbon free of any heteroatoms.

### Embodiment 10

The composition of embodiment 1, wherein the first solvent comprises an alkylbenzene represented by

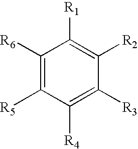

wherein R₁ is a C₁₋₃ alkyl and R₂, R₃, R₄, R₅ and R₆ are each independently hydrogen or a C₁₋₃ alkyl,
provided that R₁, R₂, R₃, R₄, R₅ and R₆ combined have a total number of carbon atoms of between 1 and 6.

### Embodiment 11

The composition of embodiment 1, wherein the carbocyclic compound comprises a benzene ring, cyclohexane ring, cyclopentane ring or a combination thereof.

### Embodiment 12

The composition of embodiment 1, wherein the carbocyclic compound has 5 to 15 carbon atoms.

### Embodiment 13

The composition of embodiment 1, wherein the carbocyclic compound has one or more substituents selected from hydroxyl, acyl, acyloxy, carboxyl ester, alkyl, alkoxy and ketone.

### Embodiment 14

The composition of embodiment 1, wherein the second solvent comprises at least one carbocyclic compound selected from salicylaldehyde, methylsalicylate, anisol, tetralin, cyclopentane, cyclopentanone, cyclohexanone, methylbenzoate, anisaldehyde, mesitylene and 2-methoxybenzaldehyde.

### Embodiment 15

The composition of embodiment 1, wherein the second solvent comprises a compound represented by

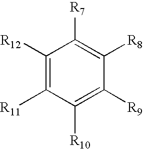

wherein R₇, R₈, R₉, R₁₀, R₁₁ and R₁₂ are each independently hydrogen, hydroxyl, acyl, acyloxy, carboxyl ester, C₁₋₅ alkyl or alkoxy.

### Embodiment 16

The composition of embodiment 1, wherein the at least one first solvent, at least one second solvent or both, are non-halogenated.

### Embodiment 17

The composition of embodiment 1, wherein said composition is substantially free of halogenated compounds.

### Embodiment 18

The composition of embodiment 1, wherein the boiling point of the first solvent is between about 109° C. and 210° C.

### Embodiment 19

The composition of embodiment 1, wherein the boiling point of the second solvent is between about 49° C. and 225° C.

### Embodiment 20

The composition of embodiment 1, comprising between about 50 wt % and 99 wt % of said at least one first solvent.

### Embodiment 21

The composition of embodiment 1, comprising between about 90 wt % and 99 wt % of said at least one first solvent.

### Embodiment 22

The composition of embodiment 1, comprising between about 50 wt % and 0.01 wt % of said at least one second solvent.

### Embodiment 23

The composition of embodiment 1, comprising between about 10 wt % and 0.01 wt % of said at least one second solvent.

### Embodiment 24

The composition of embodiment 1, wherein the weight ratio of said at least one first solvent to said at least one second solvent is between about 1000:1 and 2:1.

### Embodiment 25

The composition of embodiment 1, wherein the weight ratio of said at least one first solvent to said at least one second solvent is between about 100:1 and 10:1.

### Embodiment 26

The composition of embodiment 1, comprising between about 0.01 wt % and about 0.1 wt % of the at least one n-type material and the at least one p-type material, combined.

### Embodiment 27

A photovoltaic device comprising
an anode;
a cathode; and
an active layer located between the anode and the cathode, wherein the active layer is formed using the composition of embodiment 1.

### Embodiment 28

The photovoltaic device of embodiment 27, wherein the efficiency of said photovoltaic device is greater than about 5.0%.

### Embodiment 29

The photovoltaic device of embodiment 27, further comprising a hole transport layer located between the active layer and the anode electrode.

### Embodiment 30

A composition comprising:
at least one p-type material comprising a conjugated polymer;
at least one n-type material comprising a fullerene derivative;
at least one first solvent; and
at least one second solvent;
   wherein the first solvent is different from the second solvent, the first solvent comprises of at least one alkylbenzene or benzocyclohexane, and
   the second solvent comprises of at least one carbocyclic compound, and
   wherein said composition is substantially free of halogenated compounds.

### Embodiment 31

The composition of embodiment 30, wherein said composition is free of halogenated compounds.

### Embodiment 32

The composition of embodiment 30, wherein the first solvent is a hydrocarbon free of any heteroatoms

### Embodiment 33

The composition of embodiment 30, comprising between about 50 and 99% wt of said at least one first solvent.

### Embodiment 34

The composition of embodiment 30, comprising between about 50 and 0.01% wt of said at least one second solvent.

### Embodiment 35

The composition of embodiment 30, comprising between about 0.01 wt % and about 0.1 wt % of the at least one n-type material and the at least one p-type material, combined.

### Embodiment 36

The composition of embodiment 30, wherein the weight ratio of said at least one first solvent to said at least one second solvent is between about 1000:1 and 2:1.

### Embodiment 37

A photovoltaic device comprising
an anode;
a cathode; and
and an active layer located between the anode and the cathode, wherein the active layer is formed using the composition of embodiment 30.

### Embodiment 38

The photovoltaic device of embodiment 37, wherein the efficiency of said photovoltaic device is greater than about 5.0%.

### Embodiment 39

The photovoltaic device of embodiment 37, further comprising a hole transport layer located between the active layer and the anode electrode.

### Embodiment 40

A method comprising:
combining at least one p-type material, at least one n-type material, at least one first solvent and at least one second solvent, to form a composition,
   wherein the first solvent is different from the second solvent, and
   wherein the first solvent comprises at least one alkylbenzene or benzocyclohexane, and the second solvent comprises at least one carbocyclic compound; and
applying said composition to at least one surface.

### Embodiment 41

The method of embodiment 40, wherein said composition is applied by spin casting, ink jetting, doctor blading, spray casting, dip coating or vapor depositing.

### Embodiment 42

The method of embodiment 40, further comprising the step of annealing the composition after said composition is applied to the at least one surface.

### Embodiment 43

The method of embodiment 40, further comprising the step of annealing the composition after said composition is applied to the at least surface at a temperature and a duration sufficient to evaporate at least 99 wt % of the first and second solvents.

### Embodiment 44

The method of embodiment 40, further comprising providing a cathode and an anode such that said composition is applied to at least one surface between said anode and said cathode.

### Embodiment 45

The method of embodiment 40, wherein the at least one surface is a surface of the anode electrode.

### Embodiment 46

The method of embodiment 40, wherein said composition is applied to two or more surfaces.

### Embodiment 47

The method of embodiment 40, further comprising providing a hole transport layer between the anode electrode and the cathode electrode.

### Embodiment 48

The method of embodiment 40, wherein the at least one surface is a surface of a hole transport layer in a photovoltaic device.

### Embodiment 49

The method of embodiment 40, wherein the at least one surface is a surface of an element of a photovoltaic device.

### Embodiment 50

The method of embodiment 40, wherein said composition is substantially free of halogenated compounds.

### Embodiment 51

The method of embodiment 40, wherein said composition is free of halogenated compounds.

### Embodiment 52

The method of embodiment 40, wherein the first solvent is a hydrocarbon free of any heteroatoms

### Embodiment 53

The method of embodiment 40, comprising between about 50 wt % and 99 wt % of said at least one first solvent.

### Embodiment 54

The method of embodiment 40, comprising between about 50 wt % and 0.01 wt % of said at least one second solvent.

### Embodiment 55

The method of embodiment 40, comprising between about 0.01 wt % and about 0.1 wt % of the at least one n-type material and the at least one p-type material, combined.

### Embodiment 56

The method of embodiment 40, wherein the weight ratio of said at least one first solvent to said at least one second solvent is between about 1000:1 and 2:1.

### Embodiment 57

A photovoltaic device comprising:
an anode;
a cathode; and
an active layer formed between the anode and the cathode according to the method of embodiment 40.

### Embodiment 58

The photovoltaic device of embodiment 57, wherein the efficiency of said photovoltaic device is greater than about 5.0%.

### Embodiment 59

The photovoltaic device of embodiment 57, further comprising a hole transport layer located between the active layer and the anode electrode.

### Embodiment 60

A method of forming a photovoltaic device comprising:
providing an anode;
providing a cathode; and
forming an active layer between the anode and the cathode by applying a composition comprising at least one p-type material, at least one n-type material, at least one first solvent and at least one second solvent, to at least one surface between the anode and the cathode,
   wherein the first solvent is different from the second solvent, and
   wherein the first solvent comprises at least one alkylbenzene or benzocyclohexane, and the second solvent comprises at least one carbocyclic compound.

### Embodiment 61

The method of embodiment 60, wherein said composition is applied by spin casting, ink jetting, doctor blading, spray casting, dip coating or vapor depositing.

### Embodiment 62

The method of embodiment 60, further comprising the step of annealing the composition after said composition is applied to the at least one surface.

### Embodiment 63

The method of embodiment 60, further comprising the step of annealing the composition after said composition is applied to the at least surface at a temperature and a duration sufficient to evaporate at least 99 wt % of the first and second solvents.

### Embodiment 64

The method of embodiment 60, wherein the at least one surface is a surface of the anode electrode.

### Embodiment 65

The method of embodiment 60, wherein said composition is applied to two or more surfaces.

### Embodiment 66

The method of embodiment 60, further comprising providing a hole transport layer between the anode electrode and the cathode electrode.

### Embodiment 67

The method of embodiment 60, further comprising providing a hole transport layer, wherein the at least one surface is a surface of said hole transport layer.

### Embodiment 68

The method of embodiment 60, wherein said composition is substantially free of halogenated compounds.

### Embodiment 69

The method of embodiment 60, wherein said composition is free of halogenated compounds.

### Embodiment 70

The method of embodiment 60, wherein the first solvent is a hydrocarbon free of any heteroatoms.

### Embodiment 71

The method of embodiment 60, comprising between about 50 wt % and 99 wt % of said at least one first solvent.

### Embodiment 72

The method of embodiment 60, comprising between about 50 wt % and 0.01 wt % of said at least one second solvent.

### Embodiment 73

The method of embodiment 60, comprising between about 0.01 wt % and about 0.1 wt % of the at least one n-type material and the at least one p-type material, combined.

### Embodiment 74

The method of embodiment 60, wherein the weight ratio of said at least one first solvent to said at least one second solvent is between about 1000:1 and 2:1.

### Embodiment 75

The method of embodiment 60, wherein the efficiency of said photovoltaic device is greater than about 5.0%.

### Embodiment 76

A method of improving the efficiency of a photovoltaic device comprising:
adding to an active layer ink composition, an amount of at least one second solvent sufficient to increase the average surface roughness of the active layer formed from the active layer ink composition,
   wherein the active layer ink composition comprises at least one n-type material, at least one p-type material and at least one first solvent comprising at least one alkylbenzene or benzocyclohexane, and the at least one second solvent comprises at least one carbocyclic compound.

### Embodiment 77

The method of embodiment 76, wherein said composition is substantially free of halogenated compounds.

### Embodiment 78

The method of embodiment 76, wherein said composition is free of halogenated compounds.

### Embodiment 79

The method of embodiment 76, wherein the first solvent is a hydrocarbon free of any heteroatoms.

### Embodiment 80

The method of embodiment 76, comprising between about 50 wt % and 99 wt % of said at least one first solvent.

### Embodiment 81

The method of embodiment 76, comprising between about 50 wt % and 0.01 wt % of said at least one second solvent.

### Embodiment 82

The method of embodiment 76, comprising between about 0.01 wt % and about 0.1 wt % of the at least one n-type material and the at least one p-type material, combined.

### Embodiment 83

The method of embodiment 76, wherein the weight ratio of said at least one first solvent to said at least one second solvent is between about 1000:1 and 2:1.

### Embodiment 84

The method of embodiment 76, wherein said second solvent increases the average surface roughness of the formed solar cell active layer to between about 5 nm and about 20 nm.

### Embodiment 85

The method of embodiment 76, wherein said second solvent increases the average surface roughness of the formed solar cell active layer to between about 6 nm and about 15 nm.

### Embodiment 86

The method of embodiment 76, wherein said second solvent increases the average surface roughness of the formed solar cell active layer to between about 8 nm and about 10 nm.

### Embodiment 87

The method of embodiment 76, wherein the improvement in efficiency is at least about 1%.

### Embodiment 88

The method of embodiment 76, wherein the efficiency of the photovoltaic device formed is greater than about 5%.

### Embodiment 89

The method of embodiment 76, wherein the at least one p-type material comprises a conjugated polymer and the at least one n-type material comprises a fullerene derivative.

### Embodiment 90

A method of improving the efficiency of a photovoltaic device comprising:
adding an amount of at least one second solvent to the active layer ink composition which forms the device active layer, said ink composition comprising at least one n-type material, at least one p-type material and at least one first solvent comprising at least alkylbenzene or benzocyclohexane,
   wherein the second solvent is an organic compound having a dispersion Hansen Solubility Parameter of between about 15 MPa^{0.5} and about 20 MPa^{0.5}, a polarity Hansen Solubility Parameter of between about 5 MPa^{0.5} and about 15 MPa^{0.5} and a hydrogen bonding Hansen Solubility Parameter of between about 0.5 MPa^{0.5} and about 18 MPa^{0.5}.

### Embodiment 91

The method of embodiment 90, wherein the improvement in efficiency is at least about 1%.

### Embodiment 92

The method of embodiment 90, wherein the efficiency of the photovoltaic device is greater than about 5%.

### Embodiment 93

The method of embodiment 90, wherein the at least one p-type material comprises a conjugated polymer and the at least one n-type material comprises a fullerene derivative.

### Embodiment 94

A method of improving the efficiency of a photovoltaic device comprising:
adding an amount of at least one second solvent to the active layer ink composition which forms the device active layer, said ink composition comprising at least one n-type material, at least one p-type material and at least one first solvent comprising at least alkylbenzene or benzocyclohexane,
   wherein the second solvent is an organic compound having a solubility similar to salicylaldehyde, methylsalicylate or anisole as predicted by the Hansen Solubility Parameters of the second solvent.

### Embodiment 95

The method of embodiment 94, wherein the improvement in efficiency is at least about 1%.

### Embodiment 96

The method of embodiment 94, wherein the efficiency of the photovoltaic device formed is greater than about 5%.

### Embodiment 97

The method of embodiment 94, wherein the p-type material comprises a conjugated polymer and the n-type material comprises a fullerene derivative.

### Embodiment 98

A method of improving the efficiency of a photovoltaic device comprising:
adding an amount of at least one second solvent to a solar cell active layer ink composition, said ink composition comprising at least one n-type material, at least one p-type material and at least one first solvent comprising an alkylbenzene or benzocyclohexane,
   wherein the second solvent comprises a carbocyclic compound and represents 6% wt or less of the solar cell active layer ink composition.

### Embodiment 99

The method of embodiment 98, wherein the improvement in efficiency is at least about 1%.

### Embodiment 100

The method of embodiment 98, wherein the efficiency of the photovoltaic device formed is greater than about 5%.

### Embodiment 101

The method of embodiment 98, wherein the p-type material comprises a conjugated polymer and the n-type material comprises a fullerene derivative.

### Embodiment 102

A composition comprising:
at least one n-type material;
at least one p-type material;
at least one first solvent comprising at least one alkyl benzene or benzocyclohexane; and
at least one second solvent having a dispersion Hansen Solubility Parameter of between about 15 MPa^{0.5} and about 20 MPa^{0.5}, a polarity Hansen Solubility Parameter of between about 5 MPa^{0.5} and about 15 MPa^{0.5} and a hydrogen bonding Hansen Solubility Parameter of between about 0.5 MPa^{0.5} and about 18 MPa^{0.5}.

### Embodiment 103

A composition comprising:
at least one n-type material;
at least one p-type material;
at least one first solvent comprising at least one alkylbenzene or benzocyclohexane; and
at least one second solvent having a solubility similar to salicylaldehyde, methylsalicylate or anisole as predicted by the Hansen Solubility Parameters of the second solvent.

### Embodiment 104

A photovoltaic device comprising:
an anode;
a cathode; and
an active layer formed according to the method of any one embodiments 76, 90, 94 or 98.

### Embodiment 105

A photovoltaic device comprising:
an anode;
a cathode; and
an active layer located between the anode and the cathode
   wherein the active layer is formed from the composition of any one of embodiments 102 or 103.

### Embodiment 106

A photovoltaic device comprising:
an anode;
a cathode; and
an active layer located between the anode and the cathode
   wherein the active layer comprises at least one conjugated polymer and at least one fullerene derivative, and
   wherein the average surface roughness of the active layer is between about 5 nm and about 20 nm.

### Embodiment 107

The device of embodiment 106, wherein the average surface roughness of the active layer is between about 6 nm and about 15 nm.

### Embodiment 108

The device of embodiment 106, wherein the average surface roughness of the active layer is between about 8 nm and about 10 nm.

### Embodiment 109

The device of embodiment 106, wherein the device efficiency is at least about 5%.

### Embodiment 110

A method of improving the efficiency of a photovoltaic device comprising:
adding to an active layer ink composition, an amount of at least one second solvent sufficient to increase the average surface roughness of the active layer formed from the active layer ink composition,
   wherein the active layer ink composition comprises at least one n-type material, at least one p-type material and at least one first solvent comprising at least one alkylbenzene or benzocyclohexane, and the at least one second solvent comprises at least one carbocyclic compound, and
   wherein the second solvent constitutes about 10% or less of the active layer ink composition.

### Embodiment 111

The method of embodiment 110, wherein the average surface roughness of the active layer is between about 5 nm and about 20 nm.

### Embodiment 112

The method of embodiment 110, wherein the average surface roughness of the active layer is between about 6 nm and about 15 nm.

### Embodiment 113

The method of embodiment 110, wherein the average surface roughness of the active layer is between about 6 nm and about 15 nm.

### Embodiment 114

The method of embodiment 110, wherein the second solvent constitutes about 6% or less of the active layer ink composition.

### Embodiment 115

The method of embodiment 110, wherein the second solvent constitutes about 2% or less of the active layer ink composition.

### Embodiment 116

The method of embodiment 110, wherein the device efficiency is at least about 5%.

What is claimed is:

1. A composition comprising at least one p-type material, at least one n-type material, at least one first solvent, and at least one second solvent,
wherein the first solvent is different from the second solvent, the first solvent comprises at least one alkylbenzene or benzocyclohexane, and the second solvent comprises at least one carbocyclic compound.

2. The composition of claim 1, wherein said composition is substantially free of halogenated compounds.

3. The composition of claim 1, wherein said at least one n-type material comprises at least one fullerene derivative represented by:
F*-(R)n
and solvates, salts and mixtures thereof,
wherein n is at least one, F* comprises a fullerene having a surface which comprises six-membered and five-membered rings; and R comprises at least one optionally substituted, unsaturated or saturated, carbocyclic or heterocyclic first ring, wherein the first ring directly bonds to the fullerene.

4. The composition of claim 3, wherein R is optionally substituted indene, optionally substituted naphthyl, optionally substituted phenyl, optionally substituted pyridinyl, optionally substituted quinolinyl, optionally substituted cyclohexyl, or optionally substituted cyclopentyl.

5. The composition of claim 1, wherein said at least one first solvent comprises toluene, o-xylene, m-xylene, p-xylene, tetralin, or a combination thereof.

6. The composition of claim 1, wherein said at least one second solvent comprises salicylaldehyde, methylsalicylate, anisol, tetralin, cyclopentane, cyclopentanone, cyclohexanone, methylbenzoate, anisaldehyde, mesitylene, 2-methoxybenzaldehyde, or a combination thereof.

7. The composition of claim 1, wherein said composition comprises about 0.01 wt % to 10 wt % of said at least one second solvent.

8. A photovoltaic device comprising an anode, a cathode, and an active layer located between the anode and the cathode, wherein the active layer is prepared from the composition of claim 1.

9. A composition comprising at least one p-type material, at least one n-type material, at least one first solvent, and at least one second solvent,
wherein the first solvent is different from the second solvent, the first solvent comprises at least one alkylbenzene or benzocyclohexane, and the second solvent has a dispersion Hansen Solubility Parameter of between about 15 MPa^{0.5} and about 20 MPa^{0.5}, a polarity Hansen Solubility Parameter of between about 5 MPa^{0.5} and about 15 MPa^{0.5} and a hydrogen bonding Hansen Solubility Parameter of between about 0.5 MPa^{0.5} and about 18 MPa^{0.5}.

10. The composition of claim 9, wherein said composition is substantially free of halogenated compounds.

11. The composition of claim 9, wherein said at least one p-type material comprises at least one regioregular polythiophene derivative.

12. The composition of claim 9, wherein said at least one n-type material comprises at least one fullerene derivative represented by:
F*-(R)n
and solvates, salts and mixtures thereof,
wherein n is at least one, F* comprises a fullerene having a surface which comprises six-membered and five-membered rings; and R comprises at least one optionally substituted, unsaturated or saturated, carbocyclic or heterocyclic first ring, wherein the first ring directly bonds to the fullerene.

13. The composition of claim 12, wherein R is optionally substituted indene, optionally substituted naphthyl, optionally substituted phenyl, optionally substituted pyridinyl, optionally substituted quinolinyl, optionally substituted cyclohexyl, or optionally substituted cyclopentyl.

14. The composition of claim 9, wherein said at least one first solvent comprises toluene, o-xylene, m-xylene, p-xylene, tetralin, or a combination thereof.

15. The composition of claim 9, wherein said at least one second solvent comprises salicylaldehyde, methylsalicylate, anisol, tetralin, cyclopentane, cyclopentanone, cyclohexanone, methylbenzoate, anisaldehyde, mesitylene, 2-methoxybenzaldehyde, or a combination thereof.

16. The composition of claim 9, wherein said composition comprises about 0.01 wt % to 10 wt % of said at least one second solvent.

17. A photovoltaic device comprising an anode, a cathode, and an active layer located between the anode and the cathode, wherein the active layer is prepared from the composition of claim 9.

18. A composition comprising at least one p-type material, at least one n-type material, at least one first solvent, and at least one second solvent,
wherein the first solvent is different from the second solvent, the first solvent comprises at least one alkylbenzene or benzocyclohexane, and the second solvent having a solubility similar to salicylaldehyde, methylsalicylate or anisole as predicted by the Hansen Solubility Parameters of the second solvent.

19. The composition of claim 18, wherein said composition is substantially free of halogenated compounds.

20. The composition of claim 18, wherein said at least one p-type material comprises at least one regioregular polythiophene derivative.

21. The composition of claim 18, wherein said at least one n-type material comprises at least one fullerene derivative represented by:
F*-(R)n
and solvates, salts and mixtures thereof,
wherein n is at least one, F* comprises a fullerene having a surface which comprises six-membered and five-membered rings; and R comprises at least one optionally substituted, unsaturated or saturated, carbocyclic or heterocyclic first ring, wherein the first ring directly bonds to the fullerene.

22. The composition of claim 21, wherein R is optionally substituted indene, optionally substituted naphthyl, optionally substituted phenyl, optionally substituted pyridinyl, optionally substituted quinolinyl, optionally substituted cyclohexyl, or optionally substituted cyclopentyl.

23. The composition of claim 18, wherein said at least one first solvent comprises toluene, o-xylene, m-xylene, p-xylene, tetralin, or a combination thereof.

24. The composition of claim 18, wherein said at least one second solvent comprises salicylaldehyde, methylsalicylate, anisol, tetralin, cyclopentane, cyclopentanone, cyclohexanone, methylbenzoate, anisaldehyde, mesitylene, 2-methoxybenzaldehyde, or a combination thereof.

25. The composition of claims 18, wherein said composition comprises about 0.01 wt % to 10 wt % of said at least one second solvent.

26. A photovoltaic device comprising an anode, a cathode, and an active layer located between the anode and the cathode, wherein the active layer is prepared from the composition of claim 18.

27. A method comprising:
combining at least one p-type material, at least one n-type material, at least one first solvent and at least one second solvent, to form a composition,
wherein the first solvent is different from the second solvent, and
wherein the first solvent comprises at least one alkylbenzene or benzocyclohexane, and the second solvent comprises at least one carbocyclic compound; and
applying said composition to at least one surface.

28. The method of claim 27, further comprising the step of annealing the composition after said composition is applied to the at least surface at a temperature and a duration sufficient to evaporate at least 99 wt % of the first and second solvents.

29. The method of claim 27, wherein the at least one surface is a surface of an element of a photovoltaic device.

30. The method of claim 27, wherein said composition is substantially free of halogenated compounds.

31. The method of claim 27, wherein said at least one first solvent comprises toluene, o-xylene, m-xylene, p-xylene, tetralin, or a combination thereof.

32. The method of claim 27, wherein said at least one second solvent comprises salicylaldehyde, methylsalicylate, anisol, tetralin, cyclopentane, cyclopentanone, cyclohexanone, methylbenzoate, anisaldehyde, mesitylene, 2-methoxybenzaldehyde, or a combination thereof.

33. The method of claim 27, wherein said composition comprises about 0.01 wt % to 10 wt % of said at least one second solvent.

34. A photovoltaic device comprising:
an anode;
a cathode; and
an active layer formed between the anode and the cathode according to the method of claim 27.

35. A method of forming a photovoltaic device comprising:
providing an anode;
providing a cathode; and
forming an active layer between the anode and the cathode by applying a composition comprising at least one p-type material, at least one n-type material, at least one first solvent and at least one second solvent, to at least one surface between the anode and the cathode,
wherein the first solvent is different from the second solvent, and
wherein the first solvent comprises at least one alkylbenzene or benzocyclohexane, and the second solvent comprises at least one carbocyclic compound.

36. The method of claim 35, further comprising the step of annealing the composition after said composition is applied to the at least surface at a temperature and a duration sufficient to evaporate at least 99 wt % of the first and second solvents.

37. The method of claim 35, wherein said composition is substantially free of halogenated compounds.

38. The method of claim 35, wherein said at least one first solvent comprises toluene, o-xylene, m-xylene, p-xylene, tetralin, or a combination thereof.

39. The method of claim 35, wherein said at least one second solvent comprises salicylaldehyde, methylsalicylate, anisol, tetralin, cyclopentane, cyclopentanone, cyclohexanone, methylbenzoate, anisaldehyde, mesitylene, 2-methoxybenzaldehyde, or a combination thereof.

40. The method of claim 35, wherein said composition comprises about 0.01 wt % to 10 wt % of said at least one second solvent.

41. The photovoltaic device made according to the method of claim 35.

42. A method of improving the efficiency of a photovoltaic device comprising:
adding to an active layer ink composition an amount of at least one second solvent sufficient to increase the average surface roughness of an active layer formed from the active layer ink composition,
wherein the active layer ink composition comprises at least one n-type material, at least one p-type material, and at least one first solvent comprises at least one alkylbenzene or benzocyclohexane, and the at least one second solvent comprises at least one carbocyclic compound.

43. The method of claim 42, wherein said second solvent increases the average surface roughness to between about 5 nm and about 20 nm.

44. The method of claim 42, wherein said second solvent increases the average surface roughness to between about 6 nm and about 15 nm.

45. The method of claim 42, wherein said second solvent increases the average surface roughness to between about 8 nm and about 10 nm.

46. A method of improving the efficiency of a photovoltaic device comprising:
adding an amount of at least one second solvent to an ink composition which forms the active layer, said ink composition comprising at least one n-type material, at least one p-type material at least one first solvent comprising at least alkylbenzene or benzocyclohexane,
wherein the second solvent is an organic compound having a dispersion Hansen Solubility Parameter of between about 15 MPa^{0.5} and about 20 MPa^{0.5}, a polarity Hansen Solubility Parameter of between about 5 MPa^{0.5} and about 15 MPa^{0.5} and hydrogen bonding Hansen Solubility Parameter of between about 0.5 MPa^{0.5} and about 18 MPa^{0.5}.

47. A method of improving the efficiency of a photovoltaic device comprising an active layer comprising an average surface roughness, said method comprising:
adding an amount of at least one second solvent to an ink composition which forms the active layer, said ink composition comprising at least one n-type material, at least one p-type material at least one first solvent comprising at least alkylbenzene or benzocyclohexane, and at least one second solvent,
wherein the second solvent is an organic compound having a solubility similar to salicylaldehyde, methylsalicylate or anisole as predicted by the Hansen Solubility Parameters of the second solvent.

48. A photovoltaic device comprising:
an anode;
a cathode; and
an active layer located between the anode and the cathode
wherein the active layer comprises at least one conjugated polymer and at least one fullerene derivative, and
wherein the average surface roughness of the active layer is between about 5 nm and about 20 nm.

49. The device of claim 48, wherein the average surface roughness of the active layer is between about 6 nm and about 15 nm.

50. The device of claim 48, wherein the average surface roughness of the active layer is between about 8 nm and about 10 nm.

51. The device of claim 48, wherein the device efficiency is at least about 5%.
